(19) United States
(12) Patent Application Publication
(10) Pub. No.: US 2012/0212890 A1
(43) Pub. Date: Aug. 23, 2012

(54) COVER AND ELECTRONIC DEVICE

(76) Inventors: Hironari Hoshino, (US); Masahiko Kakizaki, (US); Takaaki Kawakami, (US); Isao Yamashita, (US); Koji Tsukuma, (US)

(21) Appl. No.: 13/398,327

(22) Filed: Feb. 16, 2012

(30) Foreign Application Priority Data
Feb. 22, 2011 (JP) 2011-036180

(51) Int. Cl. H05K 5/00

(52) U.S. Cl. 361/679.01

(57) ABSTRACT

There is provided a cover which is formed of a transparent ceramic including metal oxide crystals, and which is disposed on part of a housing of an electronic device such that the cover covers at least part of a surface of a touch panel that is housed inside the housing.

### BACKGROUND

The present disclosure relates to a cover and an electronic device.

In recent years, electronic devices such as mobile telephones and car navigation systems etc. are adopting a touch panel as an input device that is used to input information and to operate a graphical user interface (GUI) and the like (refer to Japanese Patent Application Publication No. JP-A-2007-142577, for example).

A cover is provided on a surface of the above-described touch panel, in order to inhibit damage etc. occurring on the surface due to direct contact between the touch panel and a finger or an operation body that is used to operate the touch panel. The above-described cover is generally formed, for example, of a material such as an acrylic resin, including poly(methyl methacrylate) (PMMA), a polycarbonate (PC) resin, or glass etc.

### SUMMARY

However, among operating methods for a touch panel, such as a resistive film method, an optical method or an electrostatic capacitance method, with touch panels that adopt the electrostatic capacitance method, there is a deterioration in sensitivity of detecting a position of an operating body by the touch panel, due to the touch panel being covered by the above-described cover. Main factors that cause the deterioration in the above-described position detection sensitivity are, generally, a low relative dielectric constant of a material that forms the cover, and an increase in the thickness of the cover. In general, the cover is formed of a material that has a low relative dielectric constant, such as glass. As the cover that is formed of this type of material with a low relative dielectric constant is interposed between the operating body and the touch panel, the above-described position detection sensitivity deteriorates, as a variation in the electrostatic capacity of the touch panel (caused by the operating body that is a type of conductor approaching or touching the touch panel) becomes small.

In light of the foregoing, it is possible to improve the above-described position detection sensitivity by reducing a thickness of the cover, for example. However, in this case, a mechanical strength of the cover is reduced, and there is a risk that the cover may become damaged. For that reason, it is desirable to provide a cover that has sufficient mechanical strength in practical terms and that can also inhibit a deterioration in the position detection sensitivity of the touch panel.

To address the above-described problems, the present disclosure provides a novel and improved cover and electronic device that have sufficient mechanical strength in practical terms and that are also capable of inhibiting a deterioration in position detection sensitivity of a touch panel.

According to an embodiment of the present disclosure, there is provided a cover which is formed of a transparent ceramic including metal oxide crystals, and which is disposed on part of a housing of an electronic device such that the cover covers at least part of a surface of a touch panel that is housed inside the housing.

The metal oxide may be one of zirconium dioxide and aluminum oxide.

The metal oxide may be a polycrystalline material.

An antireflective film that is formed of a material having a lower refractive index than a refractive index of the transparent ceramic may be provided on at least one of surfaces of the cover.

The touch panel may be an electrostatic capacitance touch panel.

An electronic device including a housing,

a touch panel housed in the housing, and

a cover which is formed of a transparent ceramic including metal oxide crystals, and which is disposed on part of the housing such that the cover covers at least part of a surface of the touch panel.

The housing and the cover may be integrally formed.

According to the present disclosure described above, it is possible to provide sufficient mechanical strength in practical terms and to inhibit a deterioration in position detection sensitivity of a touch panel.

### BRIEF DESCRIPTION OF THE DRAWINGS

FIG. 1 is an explanatory diagram schematically showing a structure of an electronic device according to an exemplary embodiment of the present disclosure;

FIG. 2 is an exploded perspective view showing the structure of the electronic device according to the embodiment;

FIG. 3 is a cross-sectional view showing the structure of the electronic device according to the embodiment; and

FIG. 4 is a cross-sectional view showing a structure of an electronic device according to a modified example of the embodiment.

### DETAILED DESCRIPTION OF THE EMBODIMENT(S)

Hereinafter, preferred embodiments of the present disclosure will be described in detail with reference to the appended drawings. Note that, in this specification and the appended drawings, structural elements that have substantially the same function and structure are denoted with the same reference numerals, and repeated explanation of these structural elements is omitted.

Note that the explanation will .be made in the following order.

1. Overview of electronic device 1000 according to embodiment of present disclosure

2. Detailed structure of electronic device 1000

3. Manufacturing method of electronic device 1000

4. Structure of electronic device 2000 according to modified example of embodiment

5. Manufacturing method of electronic device 2000

I. Overview of Electronic Device 1000 According to Embodiment of Present Disclosure

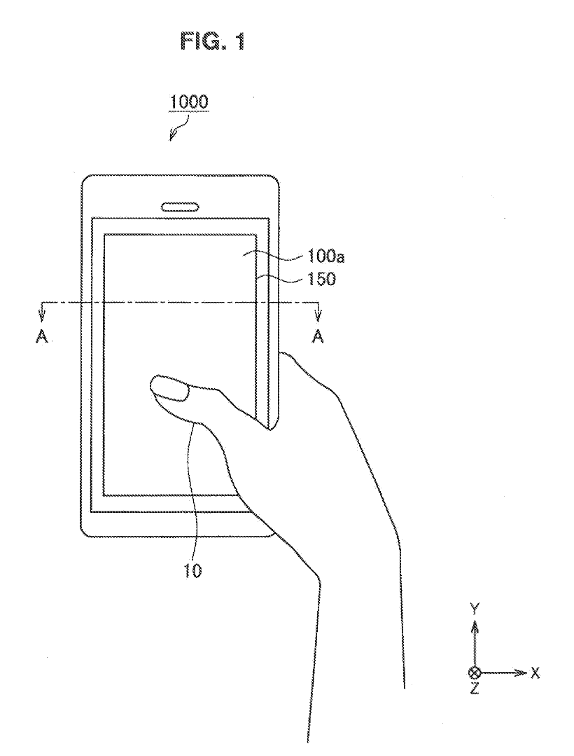

First, an overview of an electronic device 1000 according to an exemplary embodiment of the present disclosure will be explained with reference to FIG. 1. FIG. 1 is an explanatory diagram schematically showing the overview of the electronic device 1000 according to the present embodiment.

The electronic device 1000 shown in FIG. 1. is a device: that includes a touch panel (not shown in the drawings) inside a housing 110, and the touch panel is used as an input device to input information, operate a GUI and so on. The touch panel provided on the electronic device 1000 can be, for example, an electrostatic capacitance touch panel. The electrostatic capacitance touch panel detects changes in electrostatic capacity caused by an operating body 10 (a finger of a user of the electronic device 1000, for example) approaching or touching the touch panel, and the touch panel then generates and outputs information about a position of the operating, body 10 with respect to a display screen 100a, based on detection results.

Further, when the touch panel is operated using the operating body 10, there is direct contact between the touch panel and the operating body 10 and there are cases in which there is damage etc. to the surface of the touch panel. For that reason, the electronic device according to the present embodiment is provided with a cover 150 that covers the surface of the touch panel.

It should be noted that specific examples of the electronic device 1000 include a mobile communication device such as a mobile telephone or a personal handyphone system (PHS), a mobile video/music player, and a mobile game console etc. In addition, other examples of the electronic device 1000 are devices such as a personal digital assistant (PDA) and a notebook computer or the like.

2. Detailed Structure of Electronic Device 1000

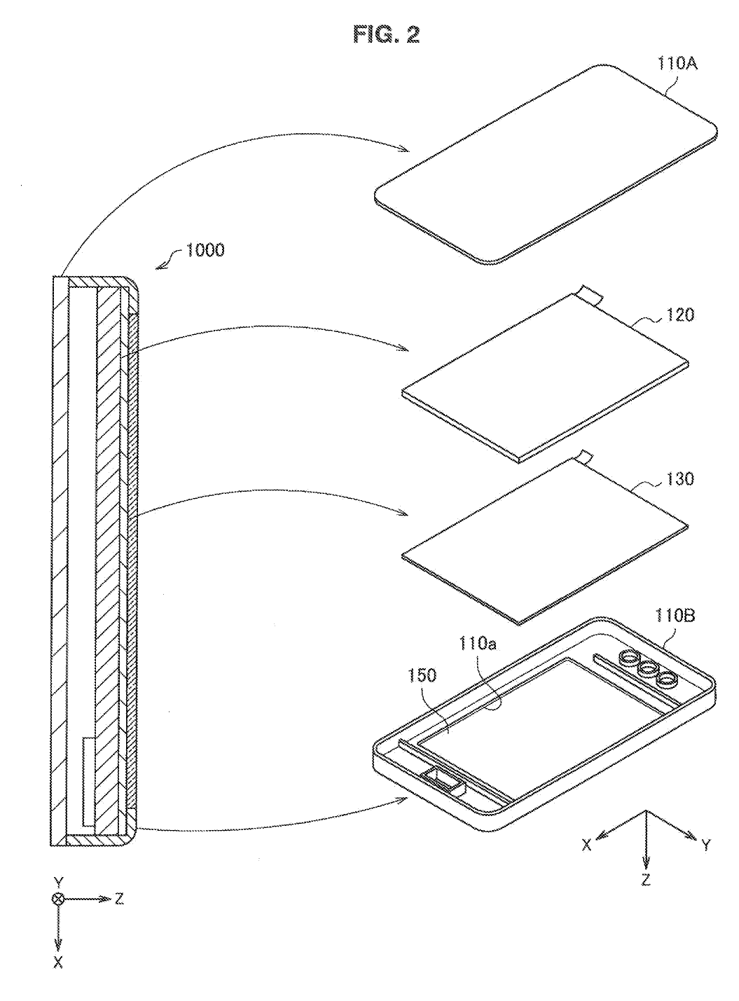

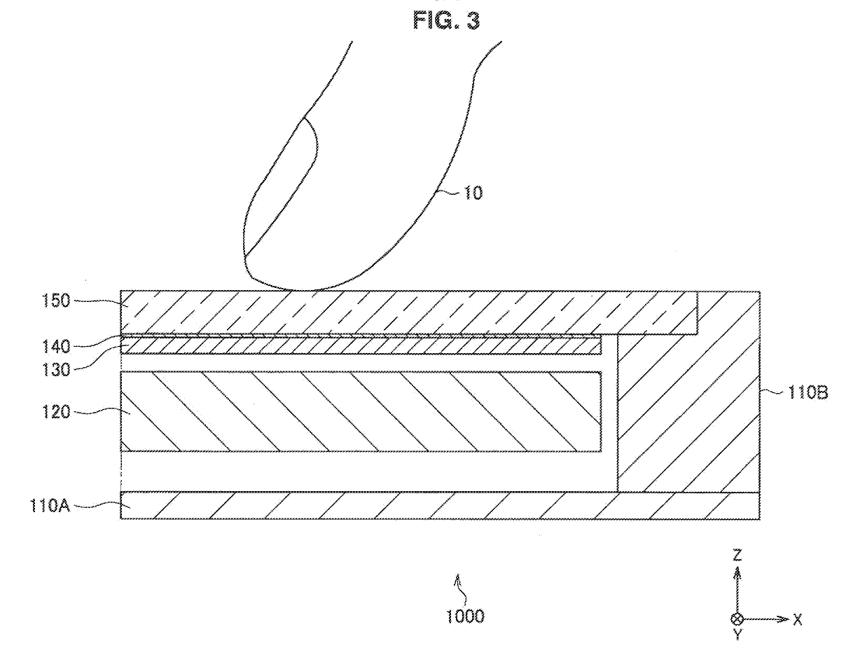

Next, the structure of the electronic device 1000 according to the present embodiment will be explained in more detail with reference to FIG. 2 and FIG. 3. FIG. 2 is an exploded perspective view showing the structure of the electronic device 1000 according to the present embodiment. FIG. 3 is a cross-sectional view showing the structure of the electronic device 1000 according to the present embodiment (a cross section of a line A-A of the electronic device 1000 shown in FIG. 1).

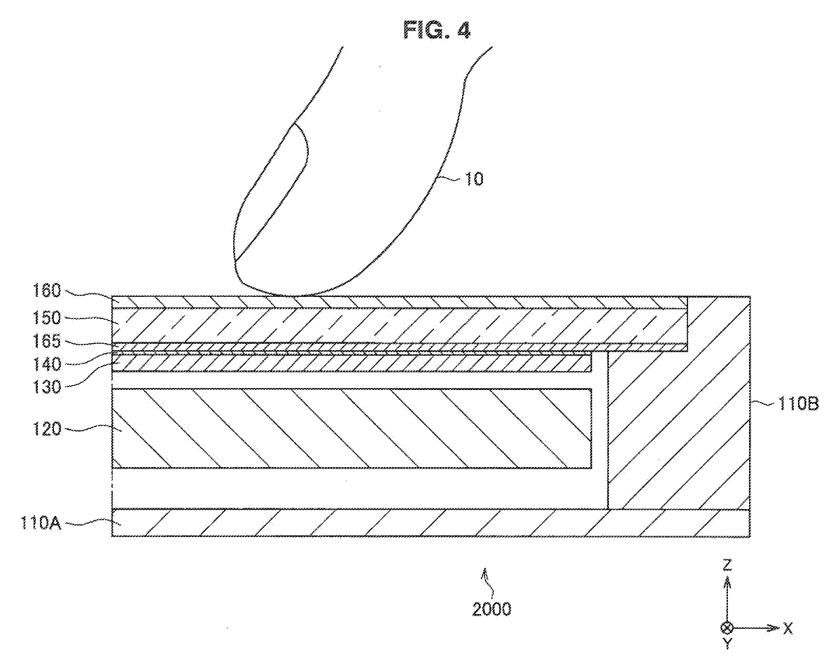

Note that, an X direction shown in FIG. 2. and FIG. 3 indicates a direction that is perpendicular to a thickness direction in which a touch panel 130 and the cover 150 are layered on a display device 120. Further, a Y direction shown in FIG. 2 and FIG. 3 indicates a direction that is perpendicular to the thickness direction in which the touch panel 130 and the cover 150 are layered on the display device 120 and that intersects with the above-described X direction. In addition, a Z direction shown in FIG. 2 and FIG. 3 indicates a direction that is the thickness direction of the touch panel 130 and the cover 150 layered on the display device 120 and that is perpendicular to an XY plane. Note that, in FIG. 4 to be explained later, an X direction, a Y direction and a Z direction are the same as the X direction, the Y direction and the Z direction shown in FIG. 2 and FIG. 3, and an explanation thereof is hereinafter omitted.

As shown in FIG. 2, the electronic device 1000 mainly includes the housing 110, the display device 120, the touch panel 130 and the cover 150.

2-1. Housing 110

The housing 110 is an, outer casing that stores the display device 120 and the touch panel 130 (to be described later) inside. The housing 110 is formed of a housing base 110A and a housing cover 110B. The housing 110 may have any shape as long as it is capable of storing the display device 120 and the touch panel 130. More specifically, for example, as shown in FIG. 2, the housing base 110A has a substantially rectangular flat plate shape and the display device 120 is installed on a side of one surface thereof. Furthermore, the housing cover 110B has a substantially cubic shape that covers the display device 120 and the touch panel 130 from above, and one surface of the housing cover 110B (the surface on the side to which the housing base 110A is attached) is open. In addition, an opening 110a is provided on a surface of the housing cover 110B that faces the surface on the side to which the housing base 110A is attached, the opening 110a being provided for attaching the cover 150 (to be described later).

A material of the housing 110, is not particularly limited, and the material used can be, for example, a resin (plastic) or a metal or a ceramic etc. Examples of the above-mentioned plastic include acrylonitrile butadiene styrene (ABS) and polycarbonate and the like. Examples of the above-mentioned metal include, for example, iron, aluminum and the like. Furthermore, examples of the above-mentioned ceramic include, for example, zirconium dioxide (ZrO₂), aluminum oxide (Al₂O₃) and the like.

Note that, when the housing 110 is formed of a ceramic, the housing 110 and the cover 150 that is formed of a transparent ceramic may be integrally formed of the same material. In this way, it is possible to improve the mechanical strength of the electronic device 1000. In this case, the housing 110 and the cover 150 may be formed in different colors. In this way, it is possible to improve the design performance of the electronic device 1000.

2-2. Display Device 120

The display device 120 displays images and a GUI etc. on a display screen, based on input signals generated by the touch panel 130 or another input device. For example, the display device 120 displays, on the display screen, an object of a select button corresponding to a desired function, and processing based on the 5. function is performed by the operating body 10 approaching or touching a location on the touch panel 130 that corresponds to a position of the select button. Note that the display device 120 is disposed such that the display screen (not shown in the drawings) is positioned on the side on which the touch panel 130 and the cover 150 are formed.

Further, the display device 120 can adopt a variety of display methods, and the display device 120 can be, for example, an organic EL display, a liquid crystal display, a field emission display (FED) or the like.

2-3. Touch Panel 130

The touch panel 130 functions as an input device to input information, operate the GUI and so on. More specifically, the touch panel 130 functions, for example, as an electrostatic capacitance touch panel that acquires position information about the operating body 10 by the operating body 10 approaching or touching the touch panel 130.

When the touch panel 130 is the electrostatic capacitance touch panel, it has electrodes having a mesh pattern (hereinafter referred to as an electrode pattern). An X axis detection pattern is formed by arranging a plurality of the electrode patterns in the X direction shown in FIG. 2 and FIG. 3. Further, a Y axis detection pattern is formed by arranging a plurality of the electrode patterns in the Y direction shown in FIG. 2 and FIG. 3.

By the operating body 10 (which is a type of conductor, such as a finger) touching or approaching a chosen position on an XY plane of this type of the touch panel 130, the above-described X axis detection pattern and the above-described Y axis detection pattern detect a change in voltage caused by an electrostatic capacity of the operating body 10. As the change in voltage is detected by the X axis detection pattern and the Y axis detection pattern in accordance with respective positions, the touch panel 130 can detect the position of the operating body 10.

Further, the touch panel 130 has a substantially rectangular membrane shape or a flat plate shape, and is disposed such that it covers the display surface side of the display device 120. In other words, in the present embodiment, as shown in FIG. 3, the touch panel 130 is disposed directly above the display device 120 in the Z axis direction.

Note that there may no gap between the touch panel 130 and the display device 120, or a noise shielding material that shuts out noise caused by the touch panel 130 may be installed between the touch panel 130 and the display device 120. Further, of the surfaces of the touch panel 130, a layer of a transparent adhesive 140, which bonds the touch panel 130 and the cover 150, may be formed on the side on which the cover 150 is disposed.

2-4. Cover 150

The cover 150 has a substantially rectangular flat plate shape, and is disposed over the opening 110a of the housing cover 110B such that it covers the surface of the touch panel 130. In other words, the cover 150 is disposed directly above the touch panel 130 in the Z axis direction (when the layer of the adhesive 140 exists, the layer of the adhesive 140 is sandwiched between the cover 150 and the touch panel 130). By arranging the cover 150 in this way, it is possible to inhibit damage to the surface of the touch panel 130 by direct contact of the operating body 10 on the touch panel 130.

2-4-1. Material of Cover 150

The cover 150 is formed of a transparent material that secures visibility of the display screen. In the present embodiment, a transparent ceramic that includes metal oxide crystals is used as this type of transparent material.

Note that, with respect to the degree of transparency in the present embodiment, it is preferable for in-line transmittance of light with a wavelength of 600 nm to be 50% or, more. The higher the in-line transmittance of the cover 150, the more the visibility of the display screen of the display device 120 improves.

Further, examples of the metal oxide used as the material of the cover 150 include, for example, zirconium dioxide (zirconia), aluminum oxide (alumina), spinel (Al₂MgO₄), YAG (Y₃Al₅O₁₂) and so on. Of these metal oxides, the, aluminum oxide need not necessarily be a pure substance, but may be a corundum that includes impurities (such as sapphire that includes Fe as the impurity, or ruby that includes Cr as the impurity, for example).

In the present embodiment, one of the above-described metal oxides is used as the material of the cover 150 in order to use, as the material of the cover 150, a material that has a high relative dielectric constant and that also has large mechanical strength.

Next, based on electrostatic capacity, a detailed explanation will be given of the reasons for using a material that has a high relative dielectric constant and that also has large mechanical strength as the material of the cover 150. First, the electrostatic capacity is expressed by the following formula.

C=ε₀·εₛ·S/d (formula. 1)

C: electrostatic capacity (F), ε₀: electric constant (F/m), εₛ: relative dielectric constant of dielectric (F/m), S: area of conductors (m²), d: distance between conductors (m).

Referring to Formula 1, when a cover formed of a material that has a low relative dielectric constant is disposed on the surface of the touch panel 130, ε_{s in Formula} 1 above becomes smaller. From this, the electrostatic capacity C caused by the touching or the approach of the operating body 10 becomes smaller, and changes in voltage of the electrodes provided in the touch panel 130 become smaller. For that reason, a position detection sensitivity of the touch panel 130 deteriorates. Thus, in the present embodiment, a material with a high relative dielectric constant is used as the cover 150.

Further, when a cover that has a large thickness is disposed on the surface of the touch panel 130, a distance between the operating body 10 and the electrodes becomes larger, and d in Formula 1 above becomes larger. From this, the electrostatic capacity C caused by the touching or the approach of the operating body 10 becomes smaller, and changes in voltage of the electrodes provided in the touch panel 130 become smaller. For that reason, the position detection sensitivity of the touch panel 130 deteriorates. Thus, in the present embodiment, as the cover 150, a material is used that has large mechanical strength and that does not cause the cover 150 to have a large thickness,

By using the material with a high relative dielectric constant as the material of the cover 150 in this way, it is possible to inhibit the position detection sensitivity of the touch panel 130 from deteriorating. Further, by using the material with the large mechanical strength as the material for the cover 150, sufficient mechanical strength can be secured, even when the thickness of the cover 150 is made thin in order to avoid deterioration of the position detection sensitivity of the touch panel 130.

Next, as the metal oxide to be used as the material of the cover 150, zirconium dioxide and aluminum oxide are given as particular examples, and the advantages of the present embodiment are explained while making a comparison with glass etc. that is generally used as a material for a cover. Note that Table 1 shows relative dielectric constants, Vickers hardness and bending strength of zirconium dioxide, aluminum oxide, glass, polycarbonate and acrylic.

TABLE 1
Examples of properties of materials for cover

| | Zirconium | Aluminum | | | |
|---|---|---|---|---|---|
| | dioxide | oxide | Glass | Polycarbonate | Acrylic |
| Relative | 30 | 10 | 4-8 | 3 | 3-4 |
| dielectric | | | | | |
| constant | | | | | |
| Vickers | 1200 | 1750 | 600 | 13 | 20 |
| hardness | | | | | |
| (kgf/mm²) | | | | | |
| Bending | 200-400 | Approx. 400 | 50-100 | 95 | 120 |
| strength | | | | | |
| (MPa) | | | | | |

2-4-2. Relative Dielectric Constant

The relative dielectric constants shown in Table 1 are measured in conformity with a measuring method for dielectric properties as prescribed by JIS C2141. As shown in Table 1, the relative dielectric constant of each substance is 30 for zirconium dioxide, 10 for aluminum oxide, 4 to 8 for glass, 3 for polycarbonate, and 3 to 4 for acrylic. Namely, it can be seen that zirconium dioxide and aluminum oxide have a higher relative dielectric constant in comparison to glass, polycarbonate and acrylic, which are generally used as cover materials. In particular, it can be seen that the relative dielectric constant of zirconium dioxide is notably high.

The higher the relative dielectric constant of the cover 150, the smoother the transfer of an electric charge between the operating body 10 and the touch panel 130, thus inhibiting a deterioration in the position detection sensitivity of the touch panel 130 that, is covered by the cover 150. As a result, it can be said to be preferable to use zirconium dioxide or aluminum oxide, which have a high relative dielectric constant, as the material of the cover 150. In addition, when importance is placed on inhibiting as much as possible the deterioration in the position detection sensitivity of the touch panel 130, it is especially preferable to use zirconium dioxide, which has a particularly high relative dielectric constant, as the material of the cover 150.

2-4-3. Vickers Hardness

The Vickers hardnesses shown in Table 1 are measured in conformity with a Vickers harness measuring method as prescribed by JIS R1610. As shown in Table 1, the Vickers hardness of each of the substances is 1200 kgf/mm² for zirconium dioxide, 1750 kgf/mm2 for aluminum oxide, 600 kgf/mm² for glass, 13 kgf/mm² for polycarbonate, and 20 kgf/mm² for acrylic. Namely, it can be seen that zirconium dioxide and aluminum oxide have a high Vickers hardness in comparison to glass, polycarbonate and acrylic, which are generally used as cover materials.

The higher the Vickers hardness of the cover 150, the more damage caused by friction on the surface is inhibited. For example, if a transparent ceramic is used, it is hard to cause damage even when rubbed with a metal. As a result, it can be said to be preferable to use zirconium dioxide or aluminum oxide, which have a high Vickers hardness, as the material of the cover 150.

2-4-4. Bending Strength

The bending strengths shown in Table 1 are measured in conformity with a measuring method for bending strength as prescribed by JIS R1601. As shown in Table 1, the bending strength of each of the substances' is 200 to 400 MPa for zirconium dioxide, approximately 400 MPa for aluminum oxide, 50 to 100 MPa for glass, 95 MPa for polycarbonate and 120 MPa for acrylic. Namely, it can be seen that zirconium dioxide' and aluminum oxide have a higher bending strength in comparison to glass, polycarbonate and acrylic, which are generally used as cover materials.

The higher the bending strength of the cover 150, the more deformation caused by an external force is suppressed. In this way, it is possible to inhibit damage caused by changes in an external force on the internal liquid crystal display and substrate etc. As a result, it can be said to be preferable to use zirconium dioxide or, aluminum oxide, which have a high bending strength, as the material of the cover 150.

Furthermore, the above-described metal oxide may be a monocrystalline material or may be a polycrystalline material. It should be noted that, in comparison to a monocrystalline material, with a polycrystalline material, it is possible to use various molding methods that are general manufacturing methods for ceramics, such as press molding, slip casting, injection molding, extrusion molding, tape casting and so on, and it is thus easy to mold a variety of shapes. For that reason, it is preferable for the cover 150 to be formed from a polycrystalline metal oxide rather than from a monocrystalline metal oxide, such as cubic zirconia or the like, for example.

3. Manufacting Method of Electronic Device 1000

Next, a manufacturing method of the electronic device 1000 that includes the cover 150 according to the embodiment of the present disclosure will be explained.

First, a commercially available metal oxide powder can be used as the metal oxide that forms the cover 150. The commercially available metal oxide power may be, for example, zirconia powder (TZ-8Y) manufactured by the Tosoh Corporation. A forming method for the cover 150 is not particularly limited as long as the above-described metal oxide can be formed in a flat plate shape, and forming methods include sintering after forming a desired shape by press molding, slip casting, injection molding, extrusion molding or tape casting, for example. Alternative methods include, for example, mechanically processing a commercially available monocrystalline material into a desired shape.

Next, as shown in FIG. 2, the cover 150 is fitted into the opening 110a of the housing cover 110B. Here, the housing cover 110B may be formed of a similar type of material as the transparent ceramic from which the cover 150 is formed. In that case, the housing 110 and the cover 150 may be integrally formed. A method to integrally form the housing 110 and the cover 150 includes extrusion molding or the like. Further, at this time, the housing 110 and the cover 150 can be formed (by two-color molding) such that the housing 110 and the cover 150 each have a different color. By integrally forming the housing 110 and the cover 150 in this way, it is possible to secure the strength of the housing 110 and also to improve manufacturing efficiency of the electronic device 1000.

Next, the housing base 110A, the display device 120, the touch panel 130 and the cover 150 are arranged to be sequentially laminated in that order, and finally, the housing base 110A and the housing cover 110B are bonded. As a result, as shown in FIG. 3, the display device 120, the touch panel 130 and the cover 150 are in a sequentially laminated state in the Z axis direction, and the electronic device 1000 is manufactured in which the display device 120 and the touch panel 130 are housed inside the housing 110 to which the cover 150 is attached.

Conclusion

The electronic device 1000 including the cover 150 according to the present embodiment is explained above. In the electronic device 1000, the cover 150 is formed of the metal oxide with the high relative dielectric constant, such as zirconium dioxide etc. and deterioration in the position detection sensitivity of the touch panel 130 can thus be inhibited. For example, the electronic device 1000 that includes the cover 150 formed of zirconium dioxide having a thickness of 1.6 mm has favorable position detection sensitivity compared to an electronic device that includes a cover formed of glass having a thickness of 0.7 mm.

Furthermore, in the electronic device 1000, the cover 150 is formed of the metal oxide with high mechanical strength (Vickers hardness, bending strength), such as aluminum oxide etc. and scratching and damage etc. of the cover 150 can thus be inhibited. Further, in the electronic device 1000, the cover 150 is formed of the transparent ceramic and thus favorable visibility of the display screen can be secured. In addition, by forming the cover 150 of the polycrystalline zirconium dioxide, processability can be made favorable. Furthermore, by integrally forming the housing 110 and the cover 150, manufacturing efficiency is significantly improved.

Note that, depending on, the application, the cover 150 according to the present embodiment can selectively use, as a main material, zirconium dioxide, which has the extremely high relative dielectric constant, or aluminum oxide, which has the extremely high mechanical strength, as appropriate.

4. Structure of Electronic Device 2000 According to Modified Example of Embodiment

Next, an electronic device 2000 that includes the cover 150 according to a modified example of the embodiment of the present disclosure will be explained with reference to FIG. 4. FIG. 4 is a cross-sectional view of the electronic device 2000 that includes the cover 150 according to the modified example.

As shown in FIG. 4, the electronic device 2000 mainly includes the housing 110, the display device 120, the touch panel 130, an antireflective film 160 and an antireflective film 165. The adhesive 140 may further be included between the touch panel 130 and the cover 150. The, housing 110, the display device 120, the touch panel 130 and the adhesive 140 have substantially the same structure as the housing 110, the display device 120, the touch panel 130 and the adhesive 140 according to the embodiment of the present disclosure. Thus, in the modified example, hereinafter, the explanation of the structure of the electronic device 2000 will mainly concentrate on the antireflective film 160 and the antireflective film 165, and an explanation will be omitted of the structures that are substantially the same as those described above in the embodiment of the present disclosure.

Antireflective films 160 and 165

The antireflective films 160 and 165 are formed such that they cover the surface of the cover 150, and mainly inhibit reflection, on the surface of the cover 150, of ambient light and light from the display device 120 etc., thus improving light transmittance. As long as the antireflective films 160 and 165 can cover the surface of the cover 150, they may take any form. Specifically, the antireflective films 160 and 165 have, for example, a substantially rectangular film shape. Furthermore, the antireflective film 160 may be formed on both the top and underside surfaces of the cover 150, or may be formed on only one of either the top or the underside surface. Note that FIG. 4 shows an example in which the antireflective films 160 and 165 are formed on both the top and the underside surfaces of the cover 150.

The antireflective films 160 and 165 may be a single layer film or may be a multi-layer film, but a multi-layer film, which achieves a greater antireflective effect, is preferable. In the case of a single layer film, a low refractive index material is used, and for example, magnesium fluoride (MgF₂) or silicon oxide (SiO₂) etc. that are inorganic substances may be included as a main component. Alternatively, a silicone polymer or fluorocarbon polymer etc. that are organic substances may be included as a main, component. On the other hand, in the case of the multi-layer film, films of a low refractive index material and a high refractive index material are alternately laminated. As the low refractive index material, an inorganic substance such as MgF₂ or SiO₂ is used, and as the high refractive index material, an inorganic substance such as CeO₂, TiO₂ or Nb₂O₅ is used. The more the number of laminated layers is increased, the larger the antireflective effect, but it is possible to reduce 90% or more of reflection loss with 3 to 5 layers.

The method of inhibiting light reflection by the antireflective film 160 will be explained in more detail here, taking a two-layer film as an example. When an atmospheric refractive index is n₀, a refractive index of a first layer of the antireflective film 160 is n₁, a refractive index of a second layer is n₂, a refractive index of the cover 150 is nₛ, and when n₀<n₁<nₛ<n₂, when ambient light is irradiated, part of the ambient light is reflected by a surface of the first layer of the antireflective film 160, a boundary surface between the first layer and the second layer and further by a boundary surface between the second layer of the antireflective film 160 and the cover 150. The reflected light waves mutually interfere with each other and, when a membrane thickness of each of the layers is λ/4 nm, the reflected light waves mutually cancel each other out when n₀n₂²=nₛn₁². For that reason, reflected light is reduced and light transmittance is improved.

By deposition of the antireflective film 160 on the surface of the cover 150 in this way, the reflection of ambient light is reduced. Further, it is conceivable that part of the ambient light is reflected by a boundary surface between the cover 150 and the adhesive 140 or a boundary surface between the cover 150 and the touch panel 130. For that reason, for a similar reason to the deposition of the antireflective film 160 on the cover 150, it is preferable for the antireflective film 165 to be deposited between the cover 150 and the adhesive 140 or between the cover 150 and the touch panel 130. For a similar reason to reduce reflection of the ambient light, and also from the point of view of inhibiting, the reflection of light from the display device 120 on the surface of the cover 150, it is preferable for the antireflective films 160 and 165 to be deposited on both surfaces of the cover 150.

Note that, according to. experiments performed by inventors of the present disclosure, as shown in Table 2 below, for example, with respect to a cover with a thickness of 1.58 mm on which an antireflective film is not formed (designated as “Untreated” in Table 2), in-line transmittance of light is 72%. In contrast, a cover with a thickness of 1.58 mm on which antireflective films are deposited on both surfaces (designated as “Both surface AR coating” in Table 2), in-line transmittance of light is clearly increased, at 93%.

TABLE 2
Comparison of transmittance with and without antireflective film

| | In-line transmittance |
|---|---|
| | (thickness) |
| Untreated | 72% (1.58 mm) |
| Both surface AR | 93% (1.58 mm) |
| coating | |

5. Manufacturing Method of Electronic Device 2000

Next, a manufacturing method of the electronic device 2000 that includes the cover 150 according to the modified example will be explained. The antireflective films 160 and 165 are formed by coating the above-mentioned antireflective film coating compound on the surfaces of the cover 150. Any method may be used as the coating method, such as a physical method, including the spattering method, the electron beam evaporation method, the plasma chemical vapor deposition (plasma CVD) method etc. or a chemical method, including sol-gel dip coating or spin coating of SiO₂ or TiO₂ etc. Note that, the cover 150 may be fitted into the housing 110 after deposition of the antireflective films 160 and 165 on the surfaces of the cover 150, or the cover 150 and the housing 110 may first be integrally formed and the antireflective films 160 and 165 then deposited on the surfaces of the cover 150. Additionally, with respect to the manufacturing method of the electronic device 2000 that includes the housing 110, the display device 120, the touch panel 130 and the cover 150, a similar method may be used as that of the manufacturing method of the electronic device 1000 according to the present embodiment.

Conclusion

The electronic device 2000 that includes the cover 150 according to the present embodiment is explained above. In the electronic device 2000, by forming the antireflective films 160 and 165 on the surfaces of the cover 150, as the light reflected by the surfaces of the cover 150 that has a high refractive index is reduced, visibility of the display screen is improved.

In particular, the cover 150 according to the modified example is formed of a ceramic that has a high relative dielectric constant, and thus it has a high refractive index. For that reason, there is a risk that the surface of the cover 150 will have a high reflectivity of light: In view of this, in the cover 150 according to the modified example, an effect of reducing the reflection of light by deposition of the antireflective films 160 and 165 is extremely large.

The exemplary embodiment of the present disclosure is described above in detail with, reference to the appended drawings. However, the present disclosure is not limited to these examples. It should be understood by those skilled in the art that various modifications, combinations, sub-combinations and alterations may occur depending on design requirements and other factors insofar as they are within the scope of the appended claims or the equivalents thereof.

The present disclosure contains subject matter related to that disclosed in Japanese Priority Patent Application JP 2011-036180 filed in the Japan Patent Office on Feb. 22, 2011, the entire content of which is hereby incorporated by reference.

What is claimed is:

1. A cover which is formed of a transparent ceramic including metal oxide crystals, and which is disposed on part of a housing of an electronic device such that the cover covers at least part of a surface of a touch panel that is housed inside the housing.

2. The cover according to claim 1, wherein
the metal oxide is one of zirconium dioxide and aluminum oxide.

3. The cover according to claim 1, wherein
the metal oxide is a polycrystalline material.

4. The cover according to claim 1, wherein
an antireflective film that is formed of a material having a lower refractive index than a refractive index of the transparent ceramic is provided on at least one of surfaces of the cover.

5. The cover according to claim 1, wherein
the touch panel is an electrostatic capacitance touch panel.

6. An electronic device comprising:
a housing;
a touch panel housed in the housing; and
a cover which is formed of a transparent ceramic including metal oxide crystals, and which is disposed on part of the housing such that the cover covers at least part of a surface of the touch panel.

7. The electronic device according to claim 6, wherein
the housing and the cover are integrally formed.
